(19) United States
(12) Patent Application Publication
(10) Pub. No.: US 2014/0103384 A1
(43) Pub. Date: Apr. 17, 2014

(54) LIGHT-EMITTING DEVICE

(71) Applicant: PANASONIC CORPORATION, Osaka (JP)

(72) Inventors: Shinichi TAKIGAWA, Osaka (JP); Tsuyoshi TANAKA, Osaka (JP); Takuma KATAYAMA, Kyoto (JP); Hideyuki NAKANISHI, Osaka (JP); Shinji YOSHIDA, Shiga (JP); Kazuhiko YAMANAKA, Osaka (JP)

(73) Assignee: PANASONIC CORPORATION, Osaka (JP)

(21) Appl. No.: 14/140,332

(22) Filed: Dec. 24, 2013

Related U.S. Application Data
(63) Continuation of application No. PCT/JP2012/001687, filed on Mar. 12, 2012.

(30) Foreign Application Priority Data
Jun. 29, 2011 (JP) 2011-144987

(51) Int. Cl. H01L 33/50; H01L 33/00

(52) U.S. Cl. CPC H01L 33/50; H01L 33/005
USPC 257/98; 438/29

(57) ABSTRACT

A light-emitting device includes a semiconductor light-emitting element and a fluorescent member which emits fluorescent light when irradiated with light from the semiconductor light-emitting element. The fluorescent member includes (i) oxygen-proof resin having no permeability to oxygen and (ii) resin which includes semiconductor particles having different excitation fluorescence spectra according to particle diameter and is encased in the oxygen-proof resin.

### CROSS REFERENCE TO RELATED APPLICATIONS

This is a continuation application of PCT International Application No. PCT/JP2012/001687 filed on Mar. 12, 2012, designating the United States of America, which is based on and claims priority of Japanese Patent Application No. 2011-144987 filed on Jun. 29, 2011. The entire disclosures of the above-identified applications, including the specifications, drawings and claims are incorporated herein by reference in their entirety.

### FIELD

The present invention relates to a light-emitting device in which a fluorescent material layer includes a quantum dot fluorescent material.

### BACKGROUND

High-luminance white light-emitting diodes (LEDs) have been used as light sources (light-emitting devices) of lighting apparatuses and backlights of liquid crystal display panels. Approaches have been being developed to enhance efficiency and color rendering properties of such light sources. A white LED is produced by combining a semiconductor light-emitting element which emits blue light with a green phosphor, a yellow phosphor, a red phosphor, and others. The phosphors are available as an inorganic phosphor, an organic phosphor, and a quantum dot fluorescent material including a semiconductor material. An example of a white LED including an inorganic phosphor is described in Patent Literature 1.

FIG. 9 shows a cross-sectional view illustrating a conventional light-emitting device disclosed in Patent Literature 1.

As shown in FIG. 9, the conventional light-emitting device includes: a housing 8 having electrical terminals 2 and 3 embedded therein; a semiconductor light-emitting element 1 which emits ultraviolet, blue, or green light and is disposed in the housing 8; and a composition 5 including particles of a luminous substance (inorganic luminous substance pigment) 6 and filling the inside of the housing 8 so as to enclose the semiconductor light-emitting element 1.

### CITATION LIST

### Patent Literature

### [Patent Literature 1]

Japanese Unexamined Patent Application Publication (Translation of PCT Application) No. 11-500584.

### SUMMARY

### Technical Problem

LED light sources, which are small in size and require a small amount of power, are used as key components of display apparatuses and lighting apparatuses. Approaches have been being developed to enhance efficiency and color rendering properties of the high-luminance white LEDs. A white LED is typically produced by combining a blue LED as a light source with yellow phosphor. Such phosphor of a white LED is expected to be excellent in luminescence properties and energy conversion efficiency which allow for high efficiency and improved color rendering properties. Typical phosphors for use in white LEDs are crystalline particles including rare-earth ions as activators, and are generally chemically stable. Efficiency of light absorption of such phosphors is proportional to concentration of rare earth. On the other hand, excessively high concentration of rare earth causes concentration quenching, and thereby luminous efficacy of the phosphor decreases. For this reason, it is difficult to achieve a quantum efficiency as high as 80% or more.

In view of this, various semiconductor phosphor particles have been being proposed which achieve high quantum efficiency by utilizing band-edge light absorption and band-edge luminescence. In particular, particles referred to as quantum dot fluorescent particles, which have a diameter from several nanometers to a few dozen nanometers and contain no rare earthes, are newly expected to serve as phosphors. Due to a quantum size effect, visible light of desired fluorescent spectra can be obtained by controlling the size of the quantum dot fluorescent particles of the same material. Furthermore, quantum dot fluorescent particles exhibit external quantum efficiency as high as approximately 90% due to band-edge absorption and band-edge emission, so that white LEDs including quantum dot fluorescent materials as phosphor materials have high efficiency and excellent color rendering properties.

However, quantum dot fluorescent particles have such small particle sizes that a large percentage of atoms composing each particle of quantum dot fluorescent particles are present on the surface of the particle. Because of this, quantum dot fluorescent particles are likely to be chemically unstable. In particular, photo-oxidation reaction progresses on the surface of each particle of quantum dot fluorescent particles during excitation fluorescence under high temperature, causing rapid decrease in luminous efficacy. This is a major problem of quantum dot fluorescent particles.

The present invention, conceived to address the problem, has an object of providing a light-emitting device in which quantum dot fluorescent particles are prevented from photo oxidation so that the light-emitting device is prevented from decreasing in luminous efficacy.

### Solution to Problem

To solve the problem with the conventional technique, a light-emitting device according to an aspect of the present invention which includes: a semiconductor light-emitting element; and a fluorescent member which emits fluorescent light when irradiated with light from the semiconductor light-emitting element, wherein the fluorescent member includes: a first region including semiconductor particles having different excitation fluorescence spectra according to particle diameter; and a second region having no permeability to oxygen, and the first region is encased in the second region. In this configuration, oxygen does not reach the quantum dot fluorescent particles in the first region. Photo-oxidation reaction of quantum dot fluorescent particles is thereby prevented so that decrease in luminous efficacy of the light-emitting device can be slowed.

In the light-emitting device according to an aspect of the present invention, a difference between a coefficient of thermal expansion of the first region and a coefficient of thermal expansion of the second region may be 10% or less. In this configuration, cracking of the light-emitting device because of distortion or stress caused by a difference between the coefficients of thermal expansion of the first region and the second region under temperature change is prevented.

In the light-emitting device according to an aspect of the present invention, the second region may be divided into a plurality of third regions having no permeability to oxygen. Assume that the second region is composed of a second region A and a second region B for example. In this configuration, first the second region A is formed on the light-emitting element, and then the first region is formed in a center area thereon. Next, the second region B is formed on the first region and the area surrounding the first region so that the second region A and the second region B are continuous with each other all around the first region. With this, a structure in which the first region is encased in the second region can be easily formed.

In the light-emitting device according to an aspect of the present invention the first region may be composed of only the semiconductor particles. In this configuration, the resin for the first region is not necessary for manufacturing the light-emitting device, and therefore the light-emitting device can be manufactured at a lower cost.

The light-emitting device according to an aspect of the present invention may further include a housing in which the semiconductor light-emitting element is mounted, and in the light-emitting device, the second region may be located on a surface of the semiconductor light-emitting element, and the first region may be located between the third regions. In this configuration, oxygen which permeates the housing is blocked, so that the housing can be chosen from more options.

In the light-emitting device according to an aspect of the present invention, the third regions may be in contact with the first region and encase the first region. This configuration requires fewer worker-hours for production, so that the light-emitting device can be manufactured at a lower cost.

A light-emitting device according to an aspect of the present invention includes: a semiconductor light-emitting element; a fluorescent member which emits fluorescent light when irradiated with light from the semiconductor light-emitting element; and a metal layer in contact with the fluorescent member, wherein the fluorescent member includes: a first region including semiconductor particles having different excitation fluorescence spectra according to particle diameter; and a second region having no permeability to oxygen, and the first region is encased in the second region and the metal layer. In this configuration, the metal, which has low permeability to oxygen, blocks oxygen and thereby enhances oxygen-proof properties.

A method of manufacturing a light-emitting device according to an aspect of the present invention may include: molding a second member in a housing in which a semiconductor light-emitting element is provided, inserting an injecting pipe in the second member, and injecting a first member including a fluorescent material into the second member through the injecting pipe; and removing the injecting pipe after the injecting of the first member, and encasing the first member with the second member by filling, with the second member, a hole made in the second member by the injecting pipe inserted into the second member, wherein the first member emits fluorescent light when irradiated with light from the semiconductor light-emitting element and includes semiconductor particles having different excitation fluorescence spectra according to particle diameter, and the second member has no permeability to oxygen. With this, a structure in which the first member is encased in the second member can be easily formed.

### Advantageous Effects

In the light-emitting device in the present invention, the region including quantum dot fluorescent particles is fully enclosed in a region made of an oxygen-proof material having no permeability to oxygen, so that photo-oxidation reaction of the surface of each of the quantum dot fluorescent particles is prevented. The light-emitting device therefore does not deteriorate rapidly in luminous efficacy.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 shows a cross-sectional view illustrating a configuration of a light-emitting device in Embodiment 1 of the present invention.

FIG. 2A shows a cross-sectional view illustrating a manufacturing process of the light-emitting device in Embodiment 1 of the present invention.

FIG. 2B shows a cross-sectional view illustrating the manufacturing process of the light-emitting device in Embodiment 1 of the present invention.

FIG. 2C shows a cross-sectional view illustrating the manufacturing process of the light-emitting device in Embodiment 1 of the present invention.

FIG. 2D shows a cross-sectional view illustrating the manufacturing process of the light-emitting device in Embodiment 1 of the present invention.

FIG. 2E shows a cross-sectional view illustrating the manufacturing process of the light-emitting device in Embodiment 1 of the present invention.

FIG. 3 shows a cross-sectional view illustrating a configuration of a light-emitting device in Embodiment 2 of the present invention.

FIG. 4A shows a cross-sectional view illustrating a manufacturing process of the light-emitting device in Embodiment 2 of the present invention.

FIG. 4B shows a cross-sectional view illustrating the manufacturing process of the light-emitting device in Embodiment 2 of the present invention.

FIG. 4C shows a cross-sectional view illustrating the manufacturing process of the light-emitting device in Embodiment 2 of the present invention.

FIG. 5 shows a cross-sectional view illustrating a configuration of a light-emitting device in Embodiment 3 of the present invention.

FIG. 6 shows a cross-sectional view illustrating a configuration of a light-emitting device in Embodiment 4 of the present invention.

FIG. 7 shows a cross-sectional view illustrating a configuration of a light-emitting device in Embodiment 5 of the present invention.

FIG. 8 shows a cross-sectional view illustrating a configuration of a light-emitting device in Embodiment 6 of the present invention.

FIG. 9 shows a cross-sectional view illustrating a conventional light-emitting device.

### DESCRIPTION OF EMBODIMENTS

The following describes embodiments of the present invention in detail using the drawings. Each of the embodiments described below shows a preferable specific example of the present invention. The values, materials, constituent elements, layout and connection of the constituent elements, steps, and the order of the steps in the embodiments are given not for limiting the present invention but merely for illustrative purposes only. The present invention is limited solely to the claims. Thus, among the constituent elements in the following embodiments, a constituent element not included in the independent claim providing the highest level description of the present invention is not always necessary for the present invention to solve the problem but shall be described as a constituent element of a preferable embodiment. In the drawings, constituent elements of the substantially same configuration, operation, and effect are denoted by the same reference sign.

### Embodiment 1

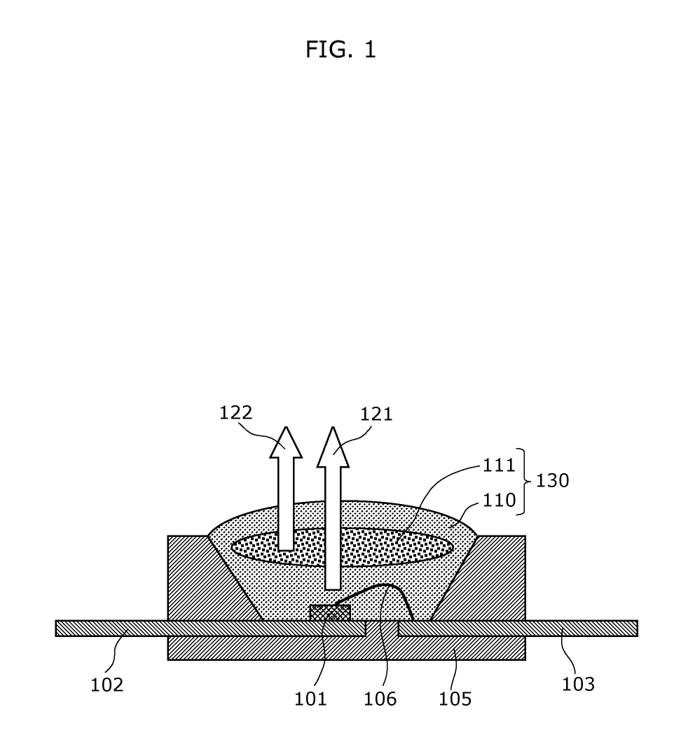

FIG. 1 shows a cross-sectional view illustrating a configuration of a light-emitting device in Embodiment 1 of the present invention.

The light-emitting device includes a semiconductor light-emitting element 101 and a fluorescent member which emits fluorescent light when irradiated with light from the light-emitting element 101. The fluorescent member 130 includes resin 111 and resin 110 encasing the resin 111. The resin 111 includes semiconductor particles which have different excitation fluorescence spectra according to particle diameter (semiconductor particles having excitation fluorescence spectra depending on the particle diameter) and forms a first region. The resin 110 forms a second region having no permeability to oxygen. The difference between the coefficient of thermal expansion of the resin 111 and the coefficient of thermal expansion of the resin 110 is, for example, 10% or less. The light-emitting device may further include a housing (package) 105 in which the light-emitting element 101 is mounted.

In the light-emitting device, electrical terminals 102 and 103 made of metal are embedded in the housing 105 made of resin; on the electrical terminal 102, the light-emitting element 101 having InGaN quantum wells in an active layer is formed. The light-emitting element 101 has an upper surface connected to the electrical terminal 103 through a gold wire 106. When voltage is applied between the electrical terminal 102 and the electrical terminal 103 to apply a current therebetween, the light-emitting element 101 emits a blue light having a wavelength of 460 nm.

The light-emitting element 101 is disposed in a recess of the housing 105 in which the resin 110 (fluorescent member 130) encloses the light-emitting element 101. The resin 110 is an oxygen-proof material having no oxygen permeability. In this case, the oxygen-proof resin 110 having no oxygen permeability is made of polyvinyl fluoride. For example, in the polyvinyl fluoride, the resin 111 is formed of silicate resin including quantum dot fluorescent particles. The quantum dot fluorescent particles each have a core-shell structure including InP as a core and come in two diameters (approximately 4.3 nm and 5.5 nm). The quantum dot fluorescent particles are photoexcited and emit green light with a center wavelength of 530 nm and red light with a center wavelength of 630 nm.

The light-emitting element 101 emits blue light 121, which passes through the resin 111 while exciting the quantum dot fluorescent particles, so that mixed light (mixed color light) 122 of green and red is emitted. As a result, the light-emitting device as a whole emits light of three primary colors of red, green, and blue to form white light.

The resin 111 including the quantum dot fluorescent particles is characterized by being encased in the resin 110, which is an oxygen-proof material and has no permeability to oxygen. The resin 111 including the quantum dot fluorescent particles is thus isolated from oxygen. As a result, the quantum dot fluorescent particles are free from temporal change caused by photo-oxidation, and therefore the light-emitting device has high reliability.

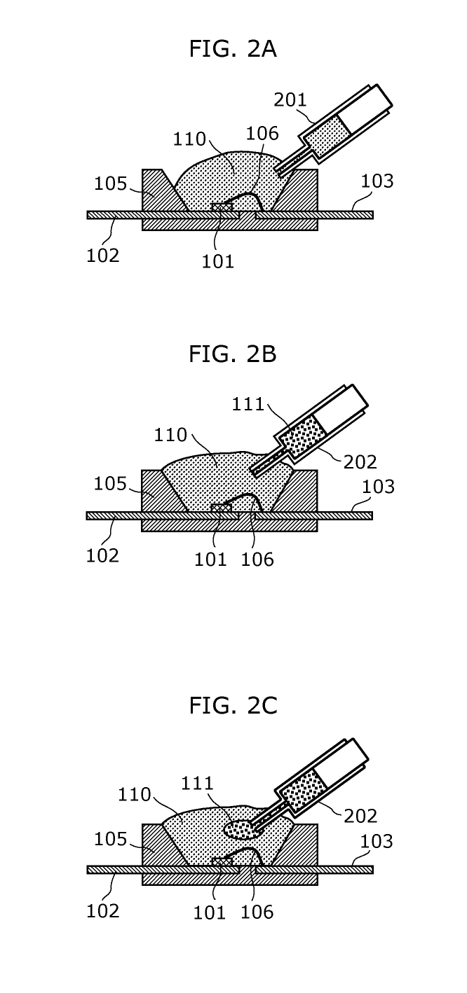

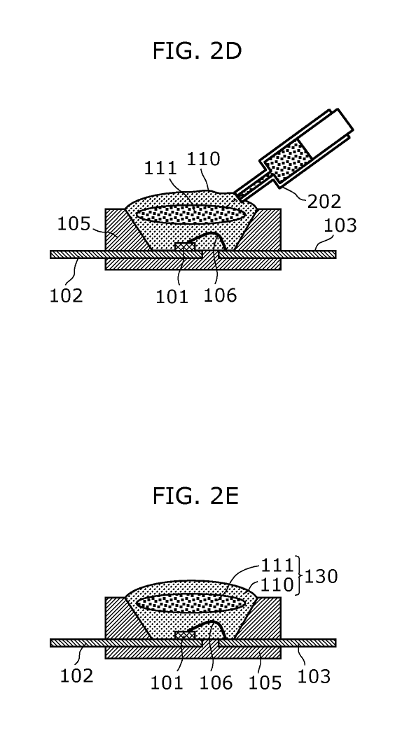

The following describes a method of manufacturing the light-emitting device in Embodiment 1. FIG. 2A to FIG. 2E show cross-sectional views illustrating a manufacturing process of the light-emitting device in Embodiment 1. The steps shown in FIG. 2A to FIG. 2E are performed in a nitrogen atmosphere or in a vacuum in order to block oxygen.

The manufacturing method includes the following steps: the resin 110 is molded as the second member in the housing 105 in which the light-emitting element 101 is already provided; next, an injecting pipe 202 is inserted into the resin 110, and the resin 111 as the first member including a fluorescent material is injected into inside the resin 110 through the injecting pipe 202 (FIG. 2B, FIG. 2C); and after the injecting of the resin 111, the injecting pipe 202 is removed and the resin 111 is encased in the resin 110 by filling, with the resin 110, the hole in the resin 110 made by the injecting pipe 202 inserted into the resin 110 (FIG. 2D). The resin 111 includes semiconductor particles having different excitation fluorescence spectra according to particle diameter (semiconductor particles having excitation fluorescence spectra depending on the particle diameter) and emits fluorescent light when irradiated with light from the light-emitting element 101. The resin 110 has no permeability to oxygen.

This method is more specifically described below. First, the resin 110, which is an oxygen-proof material and has no permeability to oxygen, is injected into a recess of the housing 105 using the injecting pipe 201. In the recess, the light-emitting element 101 is already provided before the injecting of the resin 110 (FIG. 2A). After finishing the injecting of the resin 110, the injecting pipe 201 is removed. The resin 110 still remains unhardened at this stage of the method.

Next, the tip of the injecting pipe 202 having the resin 111 therein is inserted into the resin 110 (FIG. 2B), and then the resin 111 is slowly injected into inside of the resin 110 (FIG. 2C). The injected resin 111 is covered around by the resin 110 due to surface tension of the resin 110.

Next, after a required amount of the resin 111 is injected, the injecting pipe 202 is slowly removed from the resin 110. When the injecting pipe 202 is removed, the resin 110 spontaneously flows into and fills the hole made in the resin 110 by the injecting pipe 202 inserted thereinto (FIG. 2D).

Finally, the resin 110 and the resin 111 are thermally hardened, so that the light-emitting device in FIG. 1 is completed (FIG. 2E).

Thus, the resin 111 including quantum dot fluorescent particles in the light-emitting device according to Embodiment 1 is encased in the resin 110 which is an oxygen-proof material and has no permeability to oxygen, so that the light-emitting device has high reliability.

It is preferable that an adequate additive be added to the fluorescent member 130 to lower the difference between the coefficient of thermal expansion of the resin 111 and the coefficient of thermal expansion of the resin 110 to 10% or less. The inventors of the present invention have found that when the difference in coefficient of thermal expansion is 10% or less, thermal shock to the fluorescent member 130 causes no crack between the resin 110 and the resin 111 or in either of the resin 110 or the resin 111 and no intrusion of oxygen, so that the light-emitting device has increased reliability. This can be achieved most easily by making both of the resin 111 and the resin 110 of polyvinyl fluoride (PVF). Polyvinyl fluoride has a coefficient of thermal expansion (linear expansion) of 7.1 to 7.8×10⁻⁵/K. For example, a copolymer of ethylene and chlorotrifluoroethylene (ECTFE) has a relatively low permeability to oxygen and a coefficient of thermal expansion of 8×10⁻⁵/K, which is close to that of PVF. Therefore, one of the resin 111 and the resin 110 may be made of PVF and the other may be made of ECTFE. ECTFE has a melting point of 245° C., which is higher than the melting point of PVF 203° C., and thus the resin made of ECTFE is more resistant to heat.

### Embodiment 2

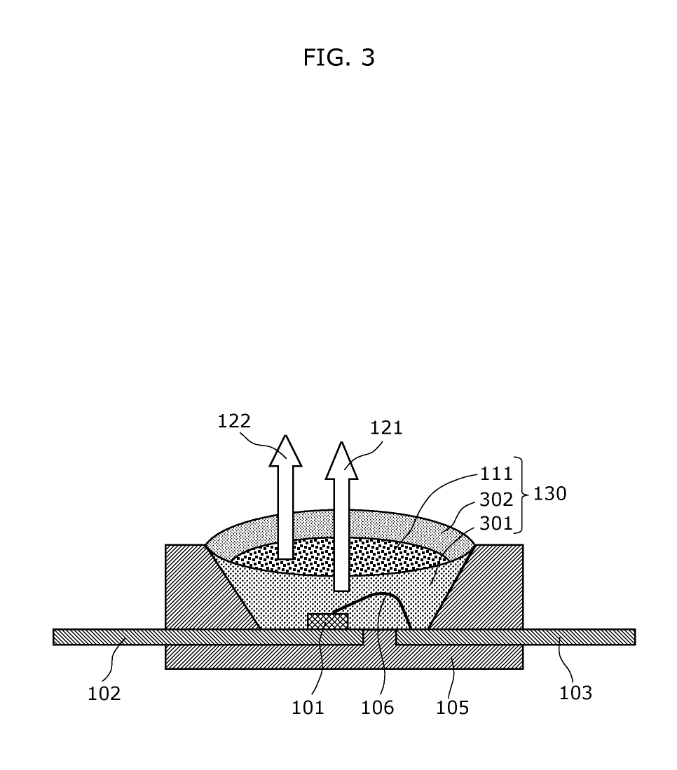

FIG. 3 shows a cross-sectional view illustrating a configuration of a light-emitting device in Embodiment 2 of the present invention. The following describes only the difference of Embodiment 2 from Embodiment 1.

The configuration of the light-emitting device in Embodiment 2 is basically the same as that of the light-emitting device shown in FIG. 1, but they are different in that in the light-emitting device in Embodiment 2, the resin 111 including quantum dot fluorescent particles is covered around by resin 301 and resin 302 both having no permeability to oxygen. In other words, the resin 110 is composed of the resin 301 and the resin 302, each of which forms a third region having no permeability to oxygen. The resin 111 forming the first region is located between the resin 301 and the resin 302, and the resin 110 forming the second region is located on the surface of the light-emitting element 101. The resin 301 and the resin 302 are in contact with the resin 111 and encase the resin 111. The resin 301 and the resin 302 may be made of polyvinyl fluoride. In this configuration, the resin 111 has no contact with oxygen, so that the light-emitting device has high reliability.

The light-emitting device in Embodiment 2 operates according to the same principle as that of the light-emitting device shown in FIG. 1. Specifically, part of the blue light 121 is emitted out by the light-emitting element 101 as it is, and the rest of the blue light 121 is emitted out after undergoing color conversion by the quantum dot fluorescent particles in the resin 111 and mixing to form mixed light 122 of green light and red light. As a result, light of three primary colors of red, green, and blue is emitted to be white light.

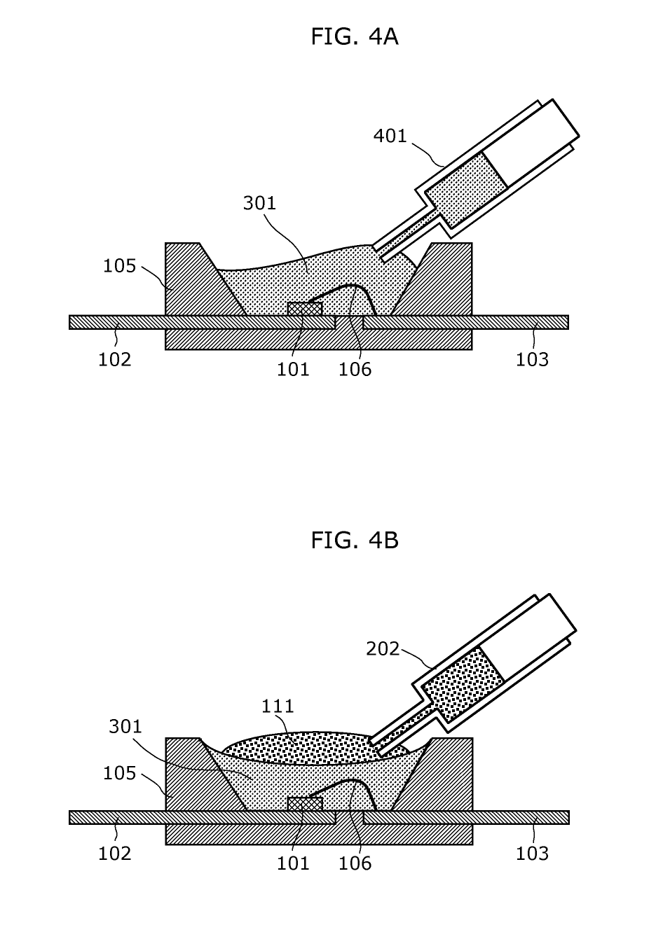

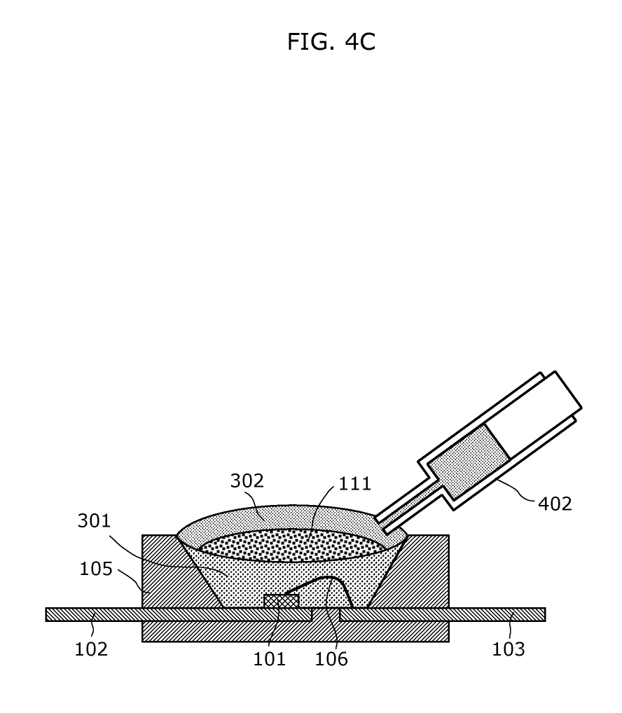

The following describes a method of manufacturing the light-emitting device in Embodiment 2. FIG. 4A to FIG. 4C show cross-sectional views illustrating a manufacturing process of the light-emitting device in Embodiment 2. The steps shown in FIG. 4A to FIG. 4C are performed in a nitrogen atmosphere or in a vacuum in order to block oxygen.

First, the resin 301, which is an oxygen-proof material and has no permeability to oxygen, is injected into a recess of the housing 105 using an injecting pipe 401. In the recess, the light-emitting element 101 is already provided before the injecting of the resin 110 (FIG. 4A).

Next, using the injecting pipe 202 having the resin 111 therein, the resin 111 is poured on the resin 301 (FIG. 4B). In this step, part of the surface of the resin 301 is left exposed in an area surrounding the resin 111.

Next, using an injecting pipe 402 having the resin 302 therein which is an oxygen-proof material and has no permeability to oxygen therein, the resin 302 is poured over the exposed surface of the resin 301 and the surface of the resin 111 (FIG. 4C). In this step, the resin 302 is poured to be continuous with the exposed surface of the resin 301 around the resin 111.

Finally, the resin 111, the resin 301, and the resin 302 are thermally hardened, so that the light-emitting device in FIG. 3 is completed.

Thus, the resin 111 including quantum dot fluorescent particles in the light-emitting device according to Embodiment 2 is encased in the resin 301 and the resin 302 which are each an oxygen-proof material and have no permeability to oxygen, so that photo-oxidation of the quantum dot fluorescent particles is prevented.

It is preferable that an adequate additive be added to the fluorescent member 130 so as to lower the difference among the coefficients of thermal expansion of the resin 111, the resin 301, and the resin 302 to 10% or less, for example. With this, even when the fluorescent member 130 undergoes thermal shock, no crack appears between the resin 111 and either of the resin 301 and the resin 302 or in any of the resin 111, the resin 301, and the resin 302, and there is no intrusion of oxygen into the fluorescent member 130, so that the light-emitting device has increased reliability.

### Embodiment 3

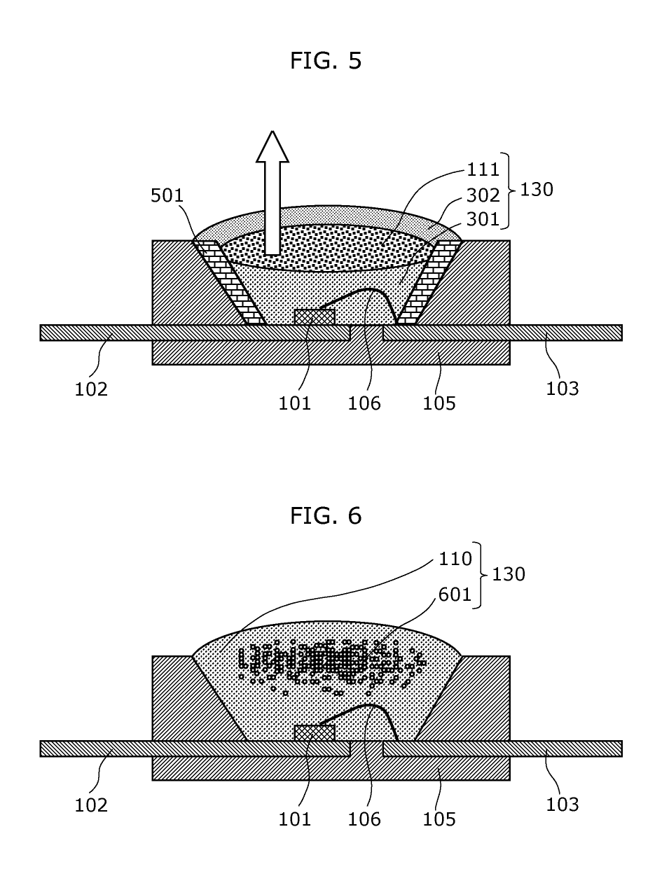

FIG. 5 shows a cross-sectional view illustrating a configuration of a light-emitting device in Embodiment 3 of the present invention. The following describes only the difference of Embodiment 3 from Embodiment 2.

The light-emitting device in Embodiment 3 and the light-emitting device in Embodiment 2 are different in that the light-emitting device in Embodiment 3 further includes a metal layer 501 at the interface between the housing 105 and the fluorescent member 130.

The light-emitting device includes a light-emitting element 101, a fluorescent member 130 which emits fluorescent light when irradiated with light from the light-emitting element 101, and the metal layer 501 in contact with the fluorescent member 130. The fluorescent member 130 includes resin 111 forming a first region, and resin 301 and resin 302 forming a second region having no permeability to oxygen. The resin 111 includes semiconductor particles having different excitation fluorescence spectra according to the particle diameter (semiconductor particles having excitation fluorescence spectra depending on the particle diameter). The resin 111 is encased in the resin 301, the resin 301, and the metal layer 501.

In Embodiment 3, the metal layer 501 is an 80-nm thick vapor-deposited aluminum.

In the light-emitting device in Embodiment 3 thus configured, the metal layer 501, resin 301, and resin 302 prevent oxygen from entering from the surface of the housing 105, so that the light-emitting device has enhanced gas barrier properties.

### Embodiment 4

FIG. 6 shows a cross-sectional view illustrating a configuration of a light-emitting device in Embodiment 4 of the present invention. The following describes only the difference of Embodiment 4 from Embodiment 1.

The light-emitting device in Embodiment 4 and the light-emitting device in Embodiment 1 are different in that the light-emitting device in Embodiment 4 includes quantum dot fluorescent particles 601 without being included in anything, instead of the resin 111 including quantum dot fluorescent particles. In other words, the first region includes only the quantum dot fluorescent particles 601, which are semiconductor particles.

In the resin 110 having no permeability to oxygen, InP quantum dot fluorescent particles, which are the quantum dot fluorescent particles 601, are present, each being surrounded by trioctylphosphine oxide (TOPO). TOPO is used in producing the InP quantum dot fluorescent particles, where TOPO functions as a ligand which prevents the quantum dot fluorescent particles from aggregation.

In this manner, the light-emitting device in Embodiment 4 need not include resin in which quantum dot fluorescent particles are included and therefore can be manufactured at a lower cost.

### Embodiment 5

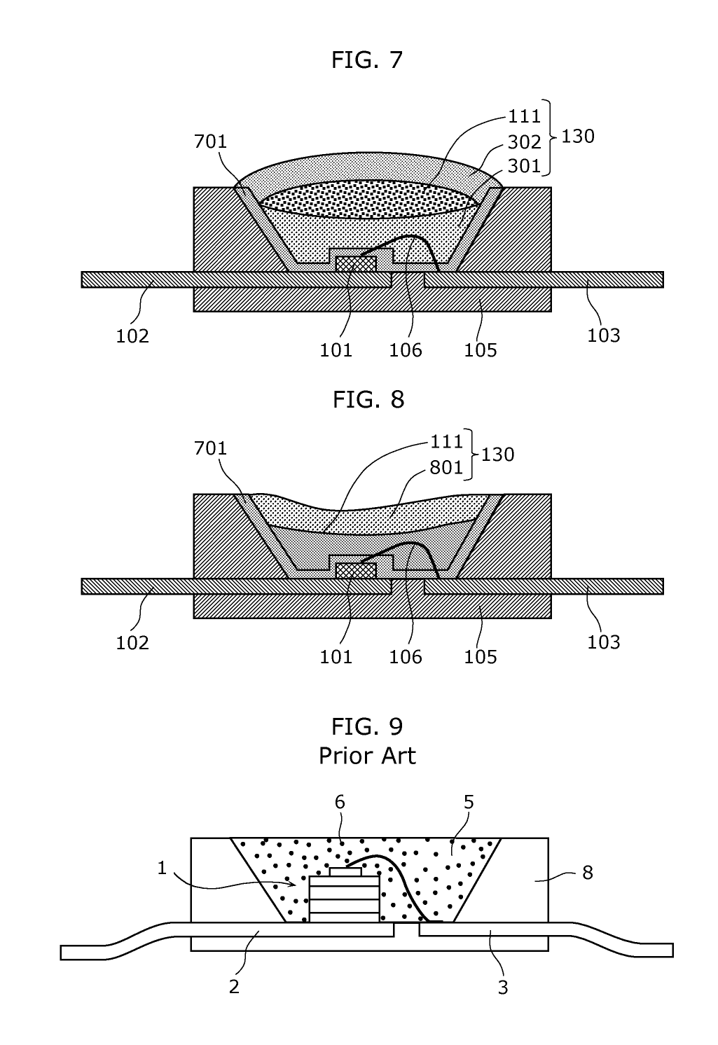

FIG. 7 shows a cross-sectional view illustrating a configuration of a light-emitting device in Embodiment 5 of the present invention. The following describes only the difference of Embodiment 5 from Embodiment 2.

The light-emitting device in Embodiment 5 and the light-emitting device in Embodiment 2 are different in that the light-emitting device in Embodiment 5 further includes a SiN film 701 which has a thickness of 50 nm and vapor-deposited in a recess where the light-emitting element 101 and the gold wire 106 are provided. In other words, the resin 111 is encased in the resin 301, the resin 302, and the SiN film 701.

The SiN film 701 has extremely low permeability to oxygen. The SiN film 701 covers the light-emitting element 101. Above the SiN film 701, the resin 301, the resin 302, and silicate resin which is the resin 111 including quantum dot fluorescent particles are formed. The resin 301 may be made of silicate, and the resin 302 may be made of polyvinyl fluoride.

In the light-emitting device in Embodiment 5 thus configured, the SiN film 701 prevents oxygen from entering from the housing 105. Furthermore, since both the resin 301 (including fluorescent particles) and the resin 111 are made of silicate, cracking at the interface between the resin 301 and the resin 111 due to heat from the light-emitting element 101 can be prevented. Thus, the light-emitting device in Embodiment 5 is highly reliable.

As with Embodiment 1, the quantum dot fluorescent particles included in the silicate resin emit green light with a center wavelength of 530 nm and red light with a center wavelength of 630 nm.

### Embodiment 6

FIG. 8 shows a cross-sectional view illustrating a configuration of a light-emitting device in Embodiment 6 of the present invention. The following describes only the difference of Embodiment 6 from Embodiment 5.

The light-emitting device in Embodiment 6 and the light-emitting device in Embodiment 5 are different in that the light-emitting device in Embodiment 6 does not include the resin 301 between the SiN film 701 and the resin 301.

The light-emitting device in Embodiment 6 includes the SiN film 701 which has a thickness of 50 nm and is vapor-deposited in a recess where the light-emitting element 101 and the gold wire 106 are provided. The SiN film 701 has extremely low permeability to oxygen. Above the SiN film 701, silicate resin which is a resin 111 including quantum dot fluorescent particles and resin 801 are formed. The resin 801 is made of polyvinyl fluoride.

In the light-emitting device in Embodiment 6 thus configured, the SiN film 701 prevents oxygen from entering from the housing 105. Furthermore, since nothing is provided between the SiN film 701 and the resin 111 and thus the resin 111 is formed directly above the SiN film 701, it is possible to transfer heat generated in the resin 111 including the quantum dot fluorescent particles (heat resulting from Stokes shift when the fluorescent particles perform color conversion) directly to the housing 105. This curbs increase in temperature of the fluorescent particles. With this, it is possible to reduce property degradation (for example, decrease in quantum efficiency or increase in wavelength of emitted light (color shift)) due to increase in temperature. Furthermore, since the resin including the quantum dot fluorescent particles is covered by a material having no permeability to oxygen, the light-emitting device in Embodiment 6 has high reliability. Thus, it is possible to provide a white LED with extremely high reliability.

As with Embodiment 1, the quantum dot fluorescent particles included in the silicate resin emit green light with a center wavelength of 530 nm and red light with a center wavelength of 630 nm.

Light-emitting devices in only some exemplary embodiments of the present invention have been described in detail above. Those skilled in the art will readily appreciate that many modifications are possible in the exemplary embodiments without materially departing from the novel teachings and advantages of the present invention. Accordingly, all such modifications are intended to be included within the scope of the present invention. The present invention also includes a different embodiment where the components in the embodiments above are used in any combination unless they depart from the spirit and scope of the present invention.

For example, in any of Embodiments 1 to 6, the oxygen-proof resin may be made any of a polystyrene-polyisobutylene-polystyrene (SIBS) block copolymer, resin of a copolymer of ethylene and vinyl alcohol (EVOH), polyvinyl alcohol resin, polyvinylidene chloride (PVDC) resin, amorphous nylon resin, and fluoropolymer resin instead of polyvinyl fluoride.

### INDUSTRIAL APPLICABILITY

Having high reliability, high efficiency, and enhanced color rendering properties, the light-emitting device according to the present invention is widely applicable to various white LED light sources such as for display devices or lighting apparatuses.

1. A light-emitting device comprising:
a semiconductor light-emitting element; and
a fluorescent member which emits fluorescent light when irradiated with light from the semiconductor light-emitting element,
wherein the fluorescent member includes: a first region including semiconductor particles having different excitation fluorescence spectra according to particle diameter; and a second region having no permeability to oxygen, and
the first region is encased in the second region.

2. The light-emitting device according to claim 1,
wherein a difference between a coefficient of thermal expansion of the first region and a coefficient of thermal expansion of the second region is 10% or less.

3. The light-emitting device according to claim 1,
wherein the second region is divided into a plurality of third regions having no permeability to oxygen.

4. The light-emitting device according to claim 1,
wherein the first region is composed of only the semiconductor particles.

5. The light-emitting device according to claim 3, further comprising
a housing in which the semiconductor light-emitting element is mounted,
wherein the second region is located on a surface of the semiconductor light-emitting element, and the first region is located between the third regions.

6. The light-emitting device according to claim 5,
wherein the third regions are in contact with the first region and encase the first region.

7. A light-emitting device comprising:
a semiconductor light-emitting element;
a fluorescent member which emits fluorescent light when irradiated with light from the semiconductor light-emitting element; and
a metal layer in contact with the fluorescent member,
wherein the fluorescent member includes: a first region including semiconductor particles having different excitation fluorescence spectra according to particle diameter; and a second region having no permeability to oxygen, and
the first region is encased in the second region and the metal layer.

8. A method of manufacturing a light-emitting device, the method comprising:
molding a second member in a housing in which a semiconductor light-emitting element is provided, inserting an injecting pipe in the second member, and injecting a first member including florescent material into the second member through the injecting pipe; and
removing the injecting pipe after the injecting of the first member, and encasing the first member with the second member by filling, with the second member, a hole made in the second member by the injecting pipe inserted into the second member,
wherein the first member emits fluorescent light when irradiated with light from the semiconductor light-emitting element and includes semiconductor particles having different excitation fluorescence spectra according to particle diameter, and
the second member has no permeability to oxygen.
